(19) United States
(12) Patent Application Publication
(10) Pub. No.: US 2007/0117268 A1
(43) Pub. Date: May 24, 2007

(54) Ball grid attachment

(75) Inventor: Samuel R. Bell, Tomball, TX (US)

Correspondence Address: GILBRETH ROEBUCK BYNUM DERRINGTON SCHMIDT WALKER;& TRAN, LLP, FROST BANK BUILDING, 6750 WEST LOOP SOUTH, SUITE 920, BELLAIRE, TX, 77401, US

(73) Assignee: Baker Hughes, Inc.

(21) Appl. No.: 11/286,628

(22) Filed: Nov. 23, 2005

(51) Int. Cl. H01L 21/00

(52) U.S. Cl. 438/119

(57) ABSTRACT

A device and method employing an electrically conductive adhesive for electrically and mechanically connecting an electrical component to a board substrate. The electrical component can includes an integrated circuit and the board may include a printed circuit board. The possible adhesives include a silver conducting RTV, silver-conducting adhesive, as well as silver conducting epoxy.

### BACKGROUND OF THE INVENTION

1. Field of the Invention

The invention relates to a method and apparatus for connecting electrical components to a substrate. More specifically, the present invention relates to a method and apparatus for providing an electrical and mechanical connection means useful for connecting electrical components, such as integrated circuits, to a substrate, such as a printed circuit board.

2. Description of Related Art

Currently many downhole tools used in the exploration and production of hydrocarbons employ sensitive electrical processing devices referred to herein as downhole electronics. One example of a downhole tool 7 having such devices is illustrated in FIG. 1, where the downhole tool 7 can be a perforator, logging tool, bond evaluation tool, formation testing device, or a seismic acquisition device, to name but a few. These tools are typically inserted on wireline 9 within a wellbore 12 that pierces a formation 6 of interest, and alternatingly raised and lowered within the wellbore 12 for conducting exploration and production operations.

As is known, electronic hardware typically involves the connection of electrical components to a substrate, where the components are often soldered to the substrate. These electrical components include digital and analog integrated circuits, processors, micro-processors, downhole sensors, cooling components, antennas, receivers, resistors, inductive elements, and capacitors, diodes, hybrids, multi-chip modules, all surface mount electronic components both passive (resistors and caps) and active (integrated circuits and op amps). The substrate provides a base on which the component is mounted and also provides dedicated electrical connectivity between various components mounted on the substrate. One example of a substrate having electrical components secured thereon is a printed circuit board. Other devices include wiring splices, connector pin to wire attachments, as well as any place where solder is typically used to make an electrical connection. Traditionally the components have pins protruding therefrom that fit into corresponding holes formed in the substrate. The pins are usually soldered within the holes to ensure electrical communication between the component and substrate and also so secure the component to the substrate.

Ball grid array (BGA) socket connectors are also used for electrically connecting an component to a substrate. A typical BGA includes solder balls, where each ball is attached to a tail of a corresponding conductive contact before the connector is mounted onto the substrate. After mounting, the solder ball is then later soldered to the associated substrate, thereby mechanically and electrically connecting the component to the substrate. BGA's have some advantages over other connectors; for example, it has no leads that may be easily damaged during handling. Also, solder balls are self-centering on die pads and can be easily attached to the tails of the conductive contacts. Still other advantages include smaller size, fine pitch, high density, better electrical performances, better package yields, to name but a few.

An example of an electrical component 19 having a BGA is shown in FIG. 2, the device 19 comprises a component housing 16, a connector rod 14, a solder ball 18, a conductor plate 20 attached to a circuit board 22. For the purposes of simplicity, only a single solder ball 18 of a BGA is shown in FIG. 2, however it is understood by skilled practitioners that a BGA can comprise a multiplicity of solder balls 18 combined with the electrical component 19. Prior to connecting the component to the substrate, the solder ball 18 is typically soldered onto the conductor rod 14. The component is then positioned onto the substrate and sufficient heating is applied to the solder ball 18 for it to adhere to the conductor plate 20.

Certain disadvantages exist however with the current methods of manufacturing downhole electronics. For example, downhole tools often experience high shock and vibration conditions either during use within a wellbore, or during handling after they have been assembled and prior to use within a wellbore. Often times the shock or vibration can damage the downhole components thereby rendering the component inoperable or ineffective. Further, the shock and vibration during use can cause the downhole component to provide erroneous data, this is especially so when the downhole component is a sensor monitoring data downhole for later analysis. The harsh downhole conditions introduce another environmental factor that must be considered, and that is the high temperature. Downhole temperatures can sometimes exceed 200° C. Moreover, many of these electronic components generate heat that adds to the heating problem of many downhole tools. For example, the components of a typical MWD system or a system attached to a wireline, such as but not limited to, a magnetometer, accelerometer, solenoid driver, microprocessor, power supply and gamma scintillator, may generate over 20 watts of heat. These high temperatures resulting from inherent downhole conditions and generated heat can sometimes affect the integrity of the downhole electronics and their associated electronic hardware. More specifically, the repeated cycles of high heating can deteriorate the solder bond that can lead to cracks in the solder that may ultimately lead to solder failure. Moreover, the elevated temperatures can re-melt the solder connections that in turn can electrically and mechanically disconnect the components from its associated substrate.

A need, therefore, exists for a reliable and efficient electrical connector for electrically and mechanically connecting electrical components to an associated substrate, where the resulting connection is able to withstand wellbore conditions.

### BRIEF SUMMARY OF THE INVENTION

The present disclosure includes a method of connecting an electrical component to a board substrate, wherein the electrical component comprises electrical leads and the board substrate comprises an electrically conducting surface. The method comprises positioning the electrical component proximate to the board substrate, applying a conductive adhesive for affixing the electrical component to the board substrate, aligning the electrical leads with corresponding locations on the electrically conducting surface, and urging the electrical component onto the board substrate. The conductive adhesive may include room temperature vulcanization (RTV), silver conducting RTV, silver conducting adhesive, silver conducting epoxy, gold conducting RTV, gold conducting adhesive, and gold conducting epoxy. The board substrate may be a printed circuit board, a hybrid module, and a multi-chip module. The electrical lead can include conducting pins and a ball grid array.

The electrical component considered for use with the present method and apparatus includes digital and analog integrated circuits, processors, micro-processors, downhole sensors, cooling components, antennas, receivers, resistors, inductive elements, capacitors, diodes, hybrids, multi-chip modules, all surface mount electronic components both passive (resistors and caps) and active (integrated circuits and op amps). The method may further include disposing the electrical component on the board substrate within a downhole tool. The downhole tool can be a perforator, a logging tool, a bond evaluation tool, a formation testing device, or a seismic acquisition device. The method can also include applying the conductive adhesive to the electrical component, to the board substrate, or both.

The present disclosure also includes a device comprising a board substrate, an electrical component, an electrical lead on the electrical component, and a conductive adhesive securingly formed between the electrical lead and the board substrate. The conductive adhesive included with the device may provide mechanical and electrical connectivity between the electrical component and the board substrate. The component for use with the present device may be a digital or analog integrated circuit, a processor, a micro-processor, a downhole sensor, a cooling component, an antenna, a receiver, a resistor, an inductive element, a capacitor, a diode, a hybrid module, a multi-chip module, all surface mount electronic components both passive (resistors and caps) and active (integrated circuits and op amps). The conductive adhesive may be temperature vulcanization (RTV), silver conducting RTV, silver conducting adhesive, silver conducting epoxy, gold conducting RTV, gold conducting adhesive, and gold conducting epoxy. The board substrate may be a printed circuit board a hybrid module, or a multi-chip module and the electrical leads may be conducting pins or a ball grid array.

### BRIEF DESCRIPTION OF THE SEVERAL VIEWS OF THE DRAWING.

FIG. 1 is a partial cross-sectional view of a downhole tool within a wellbore.

FIG. 2 is a cross sectional view of a ball grid array.

FIGS. 3a and 3b are cut-away views of embodiments of a ball grid array connector system disclosed herein.

FIG. 4 is a side view of an embodiment of an electrical component attached to a board substrate.

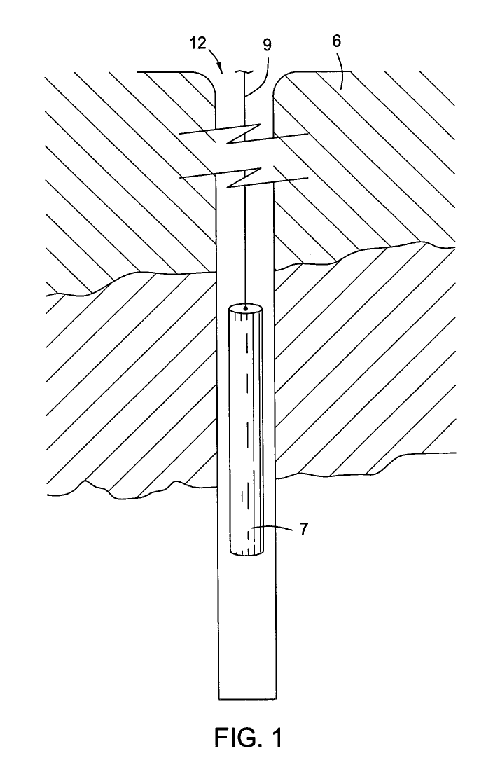

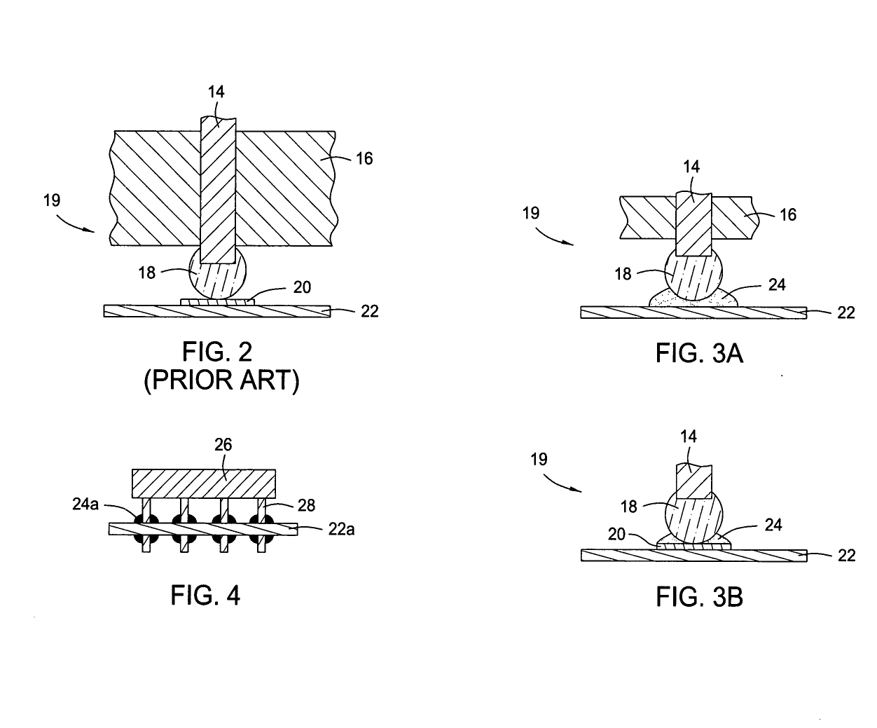

### DETAILED DESCRIPTION OF THE INVENTION

One embodiment of the method and apparatus described herein involves using an electrically conductive adhesive to connect an electrical component to a board substrate thereby forming an electrical device. Implementation of an electrically conductive adhesive provides not only an electrical connection between the component and the substrate, but also serves to mechanically affix the device to the substrate. Moreover, the flexible nature of the adhesive compensates for any stresses and shock, such as by thermal expansion, and prevents cracking or dislodging of the component, which can occur in typical connection means.

With referenced now to FIG. 3a one embodiment of a novel connection means is illustrated therein. Here, a portion of a ball grid array structure is shown connected to a circuit board. While only a single solder ball 18 is illustrated in FIG. 3a, it should be understood that the configuration illustrated is equally applicable to an entire BGA having a multiplicity of such solder balls 18. Thus an entire BGA could be secured to a substrate by applying electrically conductive adhesive to each solder ball 18, or to a selected number of solder balls 18 of an associated BGA. The solder ball 18 may operate as an electrical lead thereby allowing electrical signals to pass to and from the electrical component and the circuit board 22. As shown, the solder ball 18 is affixed onto a circuit board 22 with an amount of an electrically conducting adhesive 24 having been applied between the solder ball 18 and the circuit board 22. The adhesive for use with the present disclosure can include any conducting adhesive (including the conduction of electricity and/or thermal energy) and more specifically may comprise room temperature vulcanization (RTV), as well as metal based adhesives such as silver conducting RTV, silver conducting adhesive, silver conducting epoxy, gold conducting adhesive, and gold conducting epoxy.

The electrical component 19 of which the solder ball 18 is a part of can be any surface mounted electrical or electronic component, examples include an integrated circuit, a processor, a microprocessor, a downhole sensor, a cooling component, an antenna, a receiver, a resistor, an inductive element, a capacitor, diodes, and an operational amplifier. With regard to the circuit board 22 (also referred to herein as a board substrate), the circuit board 22 can be a printed circuit board, a hybrid board, a multi-chip module, and a connector.

With reference now to FIG. 3 another embodiment is shown therein. In this embodiment the electrical device 19 comprises all the elements as shown in FIG. 3a in addition to a conductor plate 20 that resides on the upper surface of the circuit board 22. Optionally, it may be desired to have a conductor plate 20 on the circuit board 22 for making proper electrical communication on the surface of the circuit board 22 between other devices and/or components attached to the circuit board 22. Optionally, electrically conductive traces, possibly comprised of a conducting metal such as copper, can be situated on internal layers of a board substrate, on the outside layers, or on both. In yet another embodiment of the apparatus method shown herein is illustrated in a side view in FIG. 4. Here an electrical component 26 is shown having pins 28 extending downward from its body through a circuit board 22a. It is well understood, that the pins 28 comprise conducting an electrical signal to and from the electrical component 26 and the printed board 22a. The pins 28 also comprise an electrical lead for electrical communication between the electrical device 26 and the circuit board 22a. Apertures (not shown) are formed through the circuit board 22a to accommodate for the pins passing therethrough. Optionally the electrically conducting adhesive 24a can be applied along the outer surface of the pins where they intersect the circuit board 22a. Inclusion of the electrically conductive adhesive can provide not only electrical communication between the electrical component 26 and the circuit board 22a but can also mechanically affix the electrical component 26 to the circuit board 22a.

In operation one or more of the electrical components described above may be secured to a board substrate attaching the electrically conductive adhesive either to the electrical leads of the electrical components or onto the board substrate. In one application method, the conductive adhesive may be applied to the board substrate manually with a syringe. The adhesive may optionally be applied by the use of a surface mount assembly machine. To ensure a sound bond, the plating of the respective mating surfaces should be clean and free of non-conducting detritus. One enhancement of use could include plating these surfaces with a highly conductive substance such as platinum gold. Many adhesives, such as RTV, require several hours of curing time. This time may be reduced by applying heat or ultraviolet (UV) light to the adhesive. Conductive epoxy cure time may be reduced with heat also.

Among the many uses for the electrical device constructed in the method herein described, one includes inclusion of these devices and one or more of the downhole tools described herein. As previously discussed, the harsh and rigorous environment experienced by all components of downhole tools often can cause damage to currently known construction methods of such electrical components. Accordingly implementation of the electrically conducting adhesive as herein described provides one solution to the problems of cracks and disintegration of connections that are currently being experienced.

The present invention described herein, therefore, is well adapted to carry out the objects and attain the ends and advantages mentioned, as well as others inherent therein. While a presently preferred embodiment of the invention has been given for purposes of disclosure, numerous changes exist in the details of procedures for accomplishing the desired results. These and other similar modifications will readily suggest themselves to those skilled in the art, and are intended to be encompassed within the spirit of the present invention disclosed herein and the scope of the appended claims.

1. A method of connecting an electrical component to a board, wherein the electrical component comprises electrical leads and the board comprises an electrically conducting surface, said method comprising:
applying a conductive adhesive for affixing the electrical component to the board;
aligning the electrical leads with corresponding locations on the electrically conducting surface; and
urging the electrical component onto the board.

2. The method of connecting an electrical component to a board substrate of claim 1, wherein said conductive adhesive comprises room temperature vulcanization (RTV).

3. The method of claim 1, wherein said board is selected from the list consisting of a printed circuit board, a hybrid module, and a multi-chip module.

4. The method of claim 1, wherein said electrical leads are selected from the list comprising conducting pins and a ball grid array.

5. The method of claim 1, wherein said component is selected from the list consisting of an integrated circuit, a processor, a micro-processor, a downhole sensor, a cooling component, an antenna, a receiver, a resistor, an inductive element, a capacitor, a diode, and an operational amplifier.

6. The method of claim 1, further comprising disposing the electrical component on the board wherein the board is within a downhole tool.

7. The method of claim 6, wherein said downhole tool is selected from the list consisting of a perforator, a logging tool, a bond evaluation tool, a formation testing device, and a seismic acquisition device.

8. The method of claim 1 further comprising applying the conductive adhesive to the electrical component.

9. The method of claim 1 further comprising applying the conductive adhesive to the board.

10. A method of surface mounting a component for use downhole to a printed circuit board comprising:
applying a conductive adhesive for affixing the component to the printed circuit board; and
urging the component onto the printed circuit board.

11. The method of claim 10 wherein the component is a ball grid array.

12. The method of claim 10, wherein the conductive adhesive is applied to the component.

13. The method of claim 10, wherein the conductive adhesive is applied to the printed circuit board.

14. The method of claim 11, wherein the electrical component is selected from the list consisting of an integrated circuit, a processor, a micro-processor, a downhole sensor, a cooling component, an antenna, a receiver, a resistor, an inductive element, and a capacitor.

15. The method of claim 10, further comprising disposing the electrical component on the printed circuit board wherein the printed circuit board is within a downhole tool.

16. The method of claim 15, wherein said downhole tool is selected from the list consisting of a perforator, a logging tool, a bond evaluation tool, a formation testing device, and a seismic acquisition device.

17. The method of claim 10, wherein said conductive adhesive comprises room temperature vulcanization (RTV).

18. A device for use downhole comprising:
a board;
an electrical component; and
a conductive adhesive between the electrical component and the board.

19. The device of claim 18 wherein said conductive adhesive provides mechanical and electrical connectivity between the electrical component and the board substrate.

20. The device of claim 18 wherein said component is selected from the list consisting of an integrated circuit, a processor, a micro-processor, a downhole sensor, a cooling component, an antenna, a receiver, a resistor, an inductive element, and a capacitor.

21. The device of claim 18, wherein said conductive adhesive comprises room temperature vulcanization (RTV).

22. The device of claim 21 wherein the electrical component is selected from the list consisting of an integrated circuit, a processor, a micro-processor, a downhole sensor, a cooling component, an antenna, a receiver, a resistor, an inductive element, and a capacitor.

23. The device of claim 18, wherein said board substrate is selected from the list consisting of a printed circuit board a hybrid module, or a multi-chip module.

24. The device of claim 18, wherein said electrical leads are selected from the list comprising conducting pins and a ball grid array.

25. The method of claim 2, wherein the RTV is selected from the list consisting of silver conducting RTV, silver conducting adhesive, silver conducting epoxy, gold conducting RTV, gold conducting adhesive, and gold conducting epoxy.

26. The method of claim 10 further comprising aligning the component with corresponding locations on the printed circuit board.

27. The method of claim 17, wherein the RTV is selected from the list consisting of silver conducting RTV, silver conducting adhesive, silver conducting epoxy, gold conducting RTV, gold conducting adhesive, and gold conducting epoxy.

28. The device of claim 18, wherein said device is disposed within a downhole tool.

29. The device of claim 28, wherein the downhole tool is selected from the list consisting of a perforator, a logging tool, a bond evaluation tool, a formation testing device, and a seismic acquisition device.

30. The device of claim 21, wherein the RTV is selected from the list consisting of silver conducting RTV, silver conducting adhesive, silver conducting epoxy, gold conducting RTV, gold conducting adhesive, and gold conducting epoxy.

31. The device of claim 18, wherein the conductive adhesive is not solder.

32. The device of claim 18, wherein the RTV comprises a precious metal.
